(19) United States
(12) Patent Application Publication
(10) Pub. No.: US 2026/0311642 A1
(43) Pub. Date: Oct. 8, 2026

(54) PIXEL DRIVING CIRCUIT AND DISPLAY PANEL

(71) Applicants: CHENGDU BOE OPTOELECTRONICS TECHNOLOGY CO., LTD., Chengdu, Sichuan (CN); BOE TECHNOLOGY GROUP CO., LTD., Beijing (CN); BEIJING BOE TECHNOLOGY DEVELOPMENT CO., LTD., Beijing (CN)

(72) Inventors: Bingqiang GUI, Beijing (CN); Zeliang LI, Beijing (CN); Tao GAO, Beijing (CN)

(73) Assignees: CHENGDU BOE OPTOELECTRONICS TECHNOLOGY CO., LTD., Chengdu, Sichuan (CN); BOE TECHNOLOGY GROUP CO., LTD., Beijing (CN); BEIJING BOE TECHNOLOGY DEVELOPMENT CO., LTD., Beijing (CN)

(21) Appl. No.: 19/480,392

(22) PCT Filed: Oct. 17, 2024
(86) PCT No.: PCT/CN2024/125557

§ 371 Date: Oct. 31, 2025

(30) Foreign Application Priority Data
Nov. 27, 2023 (CN) 202311595472.1

(51) Int. Cl. G09G 3/3233; G09G 3/20; H10K 59/121

(52) U.S. Cl. CPC G09G 3/3233; H10K 59/1213; G09G 3/2007; G09G 2300/0426; G09G 2300/0819; G09G 2300/0852; G09G 2300/0861

(57) ABSTRACT

A pixel driving circuit, which provided in a display panel to drive a light-emitting element, includes a driving transistor for generating a driving current; a channel region of the driving transistor is made of a metal oxide semiconductor material, and the driving transistor has only one of a top gate and a bottom gate.

### CROSS-REFERENCE TO RELATED APPLICATIONS

The present disclosure is a national phase entry under 35 USC 371 of International Patent Application No. PCT/CN2024/125557, filed on Oct. 17, 2024, which claims priority to Chinese Patent Application No. 202311595472.1, filed on Nov. 27, 2023, which are incorporated herein by reference in their entirety.

### TECHNICAL FIELD

The present disclosure relates to the field of display technologies, and in particular, to pixel driving circuit and a display panel.

### BACKGROUND

Active-matrix organic light-emitting diodes (AMOLEDs), especially flexible AMOLEDs, have become a preferred screen material for smartphones and smart watches. As the manufacturing technology of OLED display devices gradually matures and the yield of OLED display devices continues to increase, OLED costs continue to decrease, which allows OLEDs to begin to be used in more fields, such as medium and large-sized IT fields. However, for medium and large sizes, the yield of low-temperature polycrystalline silicon (LTPS) decreases, resulting in high costs. Therefore, the industry has gradually studied metal oxide thin film transistor (pure oxide TFT) backplanes as medium and large-sized OLED driving backplanes.

The above information disclosed in the background section is only for enhancement of understanding of the background of the present disclosure, and thus may contain information that does not constitute the prior art that is already known to those ordinary skill in the art.

### SUMMARY

The purpose of the present disclosure is to provide a pixel driving circuit and a display panel, to ameliorate low grayscale image quality of OLED.

To achieve the above purpose, embodiments of the present disclosure provide the following technical solutions.

In a first aspect of the present disclosure, a pixel driving circuit is provided, which is provided in a display panel to drive a light-emitting element. The pixel driving circuit includes a driving transistor for generating a driving current; a channel region of the driving transistor is made of a metal oxide semiconductor material, and the driving transistor has only one of a top gate and a bottom gate.

In an exemplary embodiment of the present disclosure, the display panel has a base substrate, a light-shielding metal layer, an inorganic buffer layer, a first gate layer, a first gate insulating layer and a semiconductor layer that are stacked in sequence; and
an active layer of the driving transistor is located in the semiconductor layer, and the driving transistor has the bottom gate located in the first gate layer, where
the pixel driving circuit further includes a storage capacitor; a first electrode plate of the storage capacitor is located in the light-shielding metal layer of the display panel, and a second electrode plate of the storage capacitor serves as the bottom gate of the driving transistor.

In an exemplary embodiment of the present disclosure, the pixel driving circuit further includes at least one switching transistor, and a channel region of a switching transistor is made of a metal oxide semiconductor material.

In an exemplary embodiment of the present disclosure, the switching transistor has a top gate and a bottom gate.

In an exemplary embodiment of the present disclosure, the display panel has a base substrate, a light-shielding metal layer, an inorganic buffer layer, a first gate layer, a first gate insulating layer, a semiconductor layer, a second gate insulating layer, a second gate layer, a planarization layer and a source-drain metal layer that are stacked in sequence;
the driving transistor includes the bottom gate located in the first gate layer and an active layer located in the semiconductor layer, and the active layer of the driving transistor includes a channel region, and a first conductive region and a second conductive region located on both sides of the channel region; each switching transistor includes a bottom gate located in the first gate layer, an active layer located in the semiconductor layer and a top gate located in the second gate layer; and the active layer of the switching transistor includes a channel region, and a first conductive region and a second conductive region located on both sides of the channel region.

In an exemplary embodiment of the present disclosure, the at least one switching transistor includes a first light-emitting control transistor;
the first light-emitting control transistor includes a bottom gate located in the first gate layer, an active layer located in the semiconductor layer, and a top gate located in the second gate layer;
the top gate and bottom gate of the first light-emitting control transistor are both used to load a first light-emitting control signal;
a first conductive region of the first light-emitting control transistor is used to load a first driving power supply voltage; and
a second conductive region of the first light-emitting control transistor is electrically connected to the first conductive region of the driving transistor through a conductive structure.

In an exemplary embodiment of the present disclosure, the at least one switching transistor includes a data writing transistor for loading a data voltage and a gate reset transistor for resetting the bottom gate of the driving transistor;
the data writing transistor includes a bottom gate located in the first gate layer, an active layer located in the semiconductor layer, and a top gate located in the second gate layer; the top gate and bottom gate of the data writing transistor are both used to load a first scan signal, and a first conductive region of the data writing transistor is used to load the data voltage;
the gate reset transistor includes a bottom gate located in the first gate layer, an active layer located in the semiconductor layer, and a top gate located in the second gate layer; the bottom gate and top gate of the gate reset transistor are both used to load a second scan signal, and a first conductive region of the gate reset transistor is used to load a first initialization voltage; and
a second conductive region of the data writing transistor, a second conductive region of the gate reset transistor, and the bottom gate of the driving transistor are electrically connected to each other through a conductive structure, where
the pixel driving circuit further includes a storage capacitor; a first electrode plate of the storage capacitor serves as the bottom gate of the driving transistor, and a second electrode plate of the storage capacitor is located in the light-shielding metal layer.

In an exemplary embodiment of the present disclosure, the pixel driving circuit further includes a storage capacitor; a first electrode plate of the storage capacitor serves as the bottom gate of the driving transistor, and a second electrode plate of the storage capacitor is located in the light-shielding metal layer;
the at least one switching transistor includes an electrode reset transistor for resetting a pixel electrode of the light-emitting element; the electrode reset transistor includes a bottom gate located in the first gate layer, an active layer located in the semiconductor layer, and a top gate located in the second gate layer; the top gate and bottom gate of the electrode reset transistor are both used to load a third scan signal, and a first conductive region of the electrode reset transistor is used to load a second initialization voltage; and
a second conductive region of the electrode reset transistor, the second electrode plate of the storage capacitor, the second conductive region of the driving transistor and the pixel electrode are electrically connected through a conductive structure.

In an exemplary embodiment of the present disclosure, the pixel driving circuit further includes a storage capacitor; a first electrode plate of the storage capacitor serves as the bottom gate of the driving transistor, and a second electrode plate of the storage capacitor is located in the light-shielding metal layer;
the at least one switching transistor includes a threshold compensation transistor and a gate reset transistor for resetting the bottom gate of the driving transistor;
the threshold compensation transistor includes a bottom gate located in the first gate layer, an active layer located in the semiconductor layer, and a top gate located in the second gate layer; the top gate and bottom gate of the threshold compensation transistor are both used to load a first scan signal, and a second conductive region of the threshold compensation transistor is electrically connected to the first conductive region of the driving transistor;
the gate reset transistor includes a bottom gate located in the first gate layer, an active layer located in the semiconductor layer, and a top gate located in the second gate layer; the bottom gate and top gate of the gate reset transistor are both used to load a first reset control signal, and a first conductive region of the gate reset transistor is used to load a first initialization voltage; and
the bottom gate of the driving transistor, a first conductive region of the threshold compensation transistor, and a second conductive region of the gate reset transistor are electrically connected to each other through a conductive structure.

In an exemplary embodiment of the present disclosure, the at least one switching transistor includes a threshold compensation transistor and a first light-emitting control transistor;
the threshold compensation transistor includes a bottom gate located in the first gate layer, an active layer located in the semiconductor layer, and a top gate located in the second gate layer; the top gate and bottom gate of the threshold compensation transistor are both used to load a first scan signal, and a first conductive region of the threshold compensation transistor is electrically connected to the bottom gate of the driving transistor;
the first light-emitting control transistor includes a bottom gate located in the first gate layer, an active layer located in the semiconductor layer, and a top gate located in the second gate layer; the bottom gate and top gate of the first light-emitting control transistor are both used to load a first light-emitting control signal, and a first conductive region of the first light-emitting control transistor is used to load a first driving power supply voltage; and
the first conductive region of the driving transistor, a second conductive region of the first light-emitting control transistor, and a second conductive region of the threshold compensation transistor are electrically connected to each other through a conductive structure.

In an exemplary embodiment of the present disclosure, the at least one switching transistor includes a data writing transistor and a second light-emitting control transistor;
the data writing transistor includes a bottom gate located in the first gate layer, an active layer located in the semiconductor layer, and a top gate located in the second gate layer; the bottom gate and top gate of the data writing transistor are both used to load a second scan signal, and a first conductive region of the data writing transistor is used to load a data voltage;
the second light-emitting control transistor includes a bottom gate located in the first gate layer, an active layer located in the semiconductor layer, and a top gate located in the second gate layer; the bottom gate and top gate of the second light-emitting control transistor are both used to load a first light-emitting control signal, and a second conductive region of the second light-emitting control transistor is electrically connected to a pixel electrode of the light-emitting element; and
the second conductive region of the driving transistor, a second conductive region of the data writing transistor, and a first conductive region of the second light-emitting control transistor are electrically connected through a conductive structure.

In an exemplary embodiment of the present disclosure, the pixel driving circuit further includes a storage capacitor; a first electrode plate of the storage capacitor serves as the bottom gate of the driving transistor, and a second electrode plate of the storage capacitor is located in the light-shielding metal layer;
the at least one switching transistor includes a second light-emitting control transistor and an electrode reset transistor for resetting a pixel electrode of the light-emitting element;
the second light-emitting control transistor includes a bottom gate located in the first gate layer, an active layer located in the semiconductor layer, and a top gate located in the second gate layer; the bottom gate and top gate of the second light-emitting control transistor are both used to load a first light-emitting control signal, and a first conductive region of the second light-emitting control transistor is electrically connected to the second conductive region of the driving transistor;
the electrode reset transistor includes a bottom gate located in the first gate layer, an active layer located in the semiconductor layer, and a top gate located in the second gate layer; the top gate and bottom gate of the electrode reset transistor are both used to load a second reset control signal, and a first conductive region of the electrode reset transistor is used to load a second initialization voltage; and
a second conductive region of the electrode reset transistor, the second electrode plate of the storage capacitor, a second conductive region of the second light-emitting control transistor and the pixel electrode are electrically connected through a conductive structure.

In an exemplary embodiment of the present disclosure, the pixel driving circuit further includes a storage capacitor; the storage capacitor includes a first electrode plate located in the first gate layer and a second electrode plate located in the light-shielding metal layer;
the at least one switching transistor includes a second light-emitting control transistor, a gate reset transistor and a data writing transistor;
the second light-emitting control transistor includes a bottom gate located in the first gate layer, an active layer located in the semiconductor layer, and a top gate located in the second gate layer; the bottom gate and top gate of the second light-emitting control transistor are both used to load a second light-emitting control signal;
the gate reset transistor includes a bottom gate located in the first gate layer, an active layer located in the semiconductor layer, and a top gate located in the second gate layer; the bottom gate and top gate of the gate reset transistor are both used to load a second reset control signal, and a first conductive region of the gate reset transistor is used to load a first initialization voltage;
a second conductive region of the second light-emitting control transistor, a second conductive region of the gate reset transistor, and the bottom gate of the driving transistor are electrically connected through a conductive structure;
the data writing transistor includes a bottom gate located in the first gate layer, an active layer located in the semiconductor layer, and a top gate located in the second gate layer; the bottom gate and top gate of the data writing transistor are both used to load a first scan signal, and a first conductive region of the data writing transistor is used to load a data voltage; and
a second conductive region of the data writing transistor, a first conductive region of the second light-emitting control transistor, and the first electrode plate of the storage capacitor are electrically connected to each other through a conductive structure.

In an exemplary embodiment of the present disclosure, the pixel driving circuit further includes an auxiliary capacitor and a storage capacitor; the auxiliary capacitor includes a first electrode plate located in the first gate layer and a second electrode plate located in the light-shielding metal layer, and the storage capacitor includes a first electrode plate located in the first gate layer and a second electrode plate located in the light-shielding metal layer;
the at least one switching transistor includes a voltage-stabilizing transistor, a data writing transistor, and an electrode reset transistor;
the voltage-stabilizing transistor includes a bottom gate located in the first gate layer, an active layer located in the semiconductor layer, and a top gate located in the second gate layer; the bottom gate and top gate of the voltage-stabilizing transistor are both used to load a second reset control signal, and a first conductive region of the voltage-stabilizing transistor is used to load a first initialization voltage;
the data writing transistor is used for loading a data voltage onto the first electrode plate of the storage capacitor in response to a first scan signal;
the electrode reset transistor includes a bottom gate located in the first gate layer, an active layer located in the semiconductor layer, and a top gate located in the second gate layer; the bottom gate and top gate of the electrode reset transistor are both used to load a first reset control signal, and a first conductive region of the electrode reset transistor is used to load a second initialization voltage; and
the second electrode plate of the auxiliary capacitor, the second electrode plate of the storage capacitor, and a second conductive region of the voltage-stabilizing transistor are electrically connected to each other through a conductive structure.

In an exemplary embodiment of the present disclosure, the conductive structure is located in one or more of the light-shielding metal layer, the first gate layer, the second gate layer, the semiconductor layer, and the source-drain metal layer.

In a second aspect of the present disclosure, a display panel is provided, including the above-mentioned pixel driving circuit.

In the pixel driving circuit and the display panel provided in the present disclosure, a top-and-bottom dual-gate structure of the driving transistor in a pixel driving circuit is changed to have only one of a top gate or a bottom gate, which reduces the electron mobility of the driving transistor, increase the SS of the driving transistor (the subthreshold swing of the thin film transistor), and better match capabilities of a driver IC, thereby ameliorating the low-grayscale image quality of an OLED display panel.

### BRIEF DESCRIPTION OF THE DRAWINGS

The above and other features as well as advantages of the present disclosure will become more apparent by describing in detail example embodiments with reference to the accompanying drawings.

FIG. 1 is an equivalent circuit diagram of a pixel driving circuit, in accordance with an embodiment of the present disclosure;

FIG. 2 is an equivalent circuit diagram of a pixel driving circuit of 5T1C, in accordance with an embodiment of the present disclosure;

FIG. 3-1 is a sectional view of a pixel driving circuit of 5T1C, in accordance with an embodiment of the present disclosure;

FIG. 3-2 is a sectional view of a pixel driving circuit of 5T1C, in accordance with an embodiment of the present disclosure;

FIG. 4 is an equivalent circuit diagram of a pixel driving circuit of 7T1C, in accordance with an embodiment of the present disclosure;

FIG. 5-1 is a sectional view of a pixel driving circuit of 7T1C, in accordance with an embodiment of the present disclosure;

FIG. 5-2 is a sectional view of a pixel driving circuit of 7T1C, in accordance with an embodiment of the present disclosure;

FIG. 6 is an equivalent circuit diagram of a pixel driving circuit of 7T2C, in accordance with an embodiment of the present disclosure;

FIG. 7-1 is a sectional view of a pixel driving circuit of 7T2C, in accordance with an embodiment of the present disclosure;

FIG. 7-2 is a sectional view of a pixel driving circuit of 7T2C, in accordance with an embodiment of the present disclosure;

FIG. 8-1 is a sectional view of a pixel driving circuit of 7T2C, in accordance with an embodiment of the present disclosure;

FIG. 8-2 is a sectional view of a pixel driving circuit of 7T2C, in accordance with an embodiment of the present disclosure; and

FIG. 9 is a graph showing an output curve of a single-gate metal oxide transistor.

### DESCRIPTION OF REFERENCE NUMERALS

T1, gate reset transistor; T2, electrode reset transistor; T3, driving transistor; T4, data writing transistor; T5, first light-emitting control transistor; T6, second light-emitting control transistor; T7a, threshold compensation transistor; T7b, voltage-stabilizing transistor; CST1, storage capacitor; CST2, auxiliary capacitor; N1, first node; N2, second node; N3, third node; N4, fourth node; N5, fifth node; OLED, light-emitting element; VDD, first driving power supply voltage; VSS, second driving power supply; Vdata, data voltage; Gate1, first scan signal; Gate2, second scan signal; Gate3, third scan signal; EM, first light-emitting control signal; EM2, second light-emitting control signal; RST1, first reset control signal; RST2, second reset control signal; Vinit1, first initialization voltage; Vinit2, second initialization voltage; SUB, base substrate; LS, light-shielding metal layer; BUF, inorganic buffer layer; GT1, first gate layer; GI1, first gate insulating layer; SCL, semiconductor layer; GI2, second gate insulating layer; GT2, second gate layer; PLN, planarization layer; SD, source-drain metal layer.

### DETAILED DESCRIPTION

Exemplary embodiments will be described more comprehensively with reference to the accompanying drawings. However, the exemplary embodiments can be implemented in various forms, and should not be construed as being limited to the examples set forth here. The provision of these embodiments makes the present disclosure more comprehensive and complete, and comprehensively conveys the concept of the exemplary embodiments to those skilled in the art. The described features, structures or characteristics may be combined in one or more embodiments in any suitable manner. In the following description, many specific details are provided to give a thorough understanding of the embodiments of the present disclosure.

The described features, structures or characteristics may be combined in one or more embodiments in any suitable manner. In the following description, many specific details are provided to give a thorough understanding of the embodiments of the present disclosure. However, those skilled in the art will recognize that the technical solutions of the present disclosure can be practiced without one or more of the specific details, or with other methods, components, materials, etc. In other situations, well-known structures, materials, or operations are not shown or described in detail to avoid obscuring the main technical ideas of the present disclosure.

The terms “a”, “an”, and “the” are used to indicate the presence of one or more elements/components. The terms “comprising” and “having” are used to indicate an open inclusion and mean that there may be additional elements/components in addition to the listed elements/components. The terms “first”, “second”, etc. are used only as labels and are not intended to limit the quantity of the objects.

In the embodiments of the present disclosure, a transistor refers to an element including at least three terminals of a gate, a source and a drain. The transistor has a channel region between the drain (a drain electrode terminal, drain region or drain electrode) and the source (a source electrode terminal, source region or source electrode), and a current can flow through the source, the channel region and the drain. The channel region refers to a region through which the current mainly flows. In the embodiments of the present disclosure, in a case where transistors with opposite polarities are used or a direction of the current in the circuit during operation changes, functions of the “source” and “drain” are sometimes interchanged. That is, the “source” and “drain” can be interchanged. In the embodiments of the present disclosure, for any transistor, one of the “source” and “drain” is referred to as a first conductive region of the transistor, and the other of the “source” and “drain” is referred to as a second conductive region of the transistor.

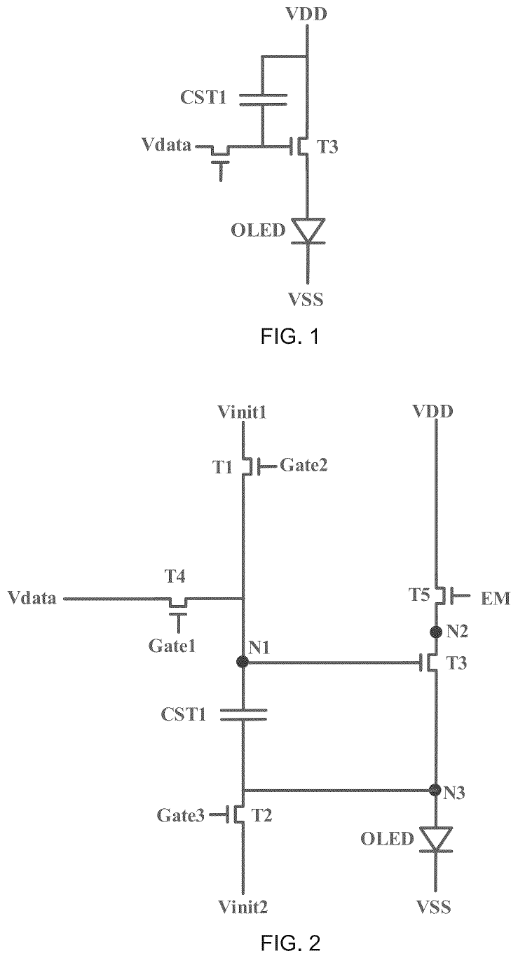

The present disclosure provides a pixel driving circuit and a display panel to which the pixel driving circuit is applied. The pixel driving circuit is disposed in the display panel to drive a light-emitting element OLED to emit light. As shown in FIG. 1, the pixel driving circuit includes a driving transistor T3 for generating a driving current, at least one switching transistor, a storage capacitor CST1, and a light-emitting element OLED. In some embodiments of the present disclosure, in order to reduce leakage current, channel regions of the driving transistor T3 and the switching transistor are both made of a metal oxide semiconductor material, e.g., indium gallium zinc oxide (IGZO) semiconductor material.

The metal oxide transistor is used as the driving transistor of each pixel driving circuit, which may ensure that the pixel driving circuits in different regions of the display panel have good uniformity. Compared with a display panel using low-temperature polysilicon transistor+metal oxide transistor technology (LTPO), the display panel in the embodiments of the present disclosure has lower manufacturing costs.

In an example, the transistors in the pixel driving circuit are all metal oxide transistors.

In an embodiment of the present disclosure, the switching transistor(s) are dual-gate transistor(s), that is, they all have a top gate and a bottom gate. In this way, the subthreshold swing of the switching transistor may be reduced, thereby improving the response speed of the switching transistor. In the embodiments of the present disclosure, in a case where the gate of the transistor is located between the channel region of the transistor and a base substrate, the gate is a bottom gate of the transistor; in a case where the gate of the transistor is located on a side of the channel region of the transistor away from the base substrate, the gate is a top gate of the transistor.

In an embodiment of the present disclosure, the driving transistor T3 has only one of a top gate and a bottom gate, and the switching transistor has a top gate and a bottom gate.

In this embodiment, the driving transistor T3 is of a single-gate structure, which may reduce the electron mobility of the driving transistor T3, increase the SS of the driving transistor T3 (the subthreshold swing of the thin film transistor), and better match capabilities of a driver IC. As a result, the low grayscale image quality of the OLED display panel is ameliorated. The switching transistor has a dual-gate structure, which may improve the response rate of the switching transistor and achieve the precise control of the switching transistor.

In an example, the driving transistor T3 has a top gate, and the switching transistor has a top gate and a bottom gate.

In another example, the driving transistor T3 has a bottom gate, and the switching transistor has a top gate and a bottom gate.

In the embodiments of the present disclosure, the driving transistor T3 and the switching transistor(s) can be N-type transistors or P-type transistors. The embodiments of the present disclosure will be described below by taking N-type transistors as an example.

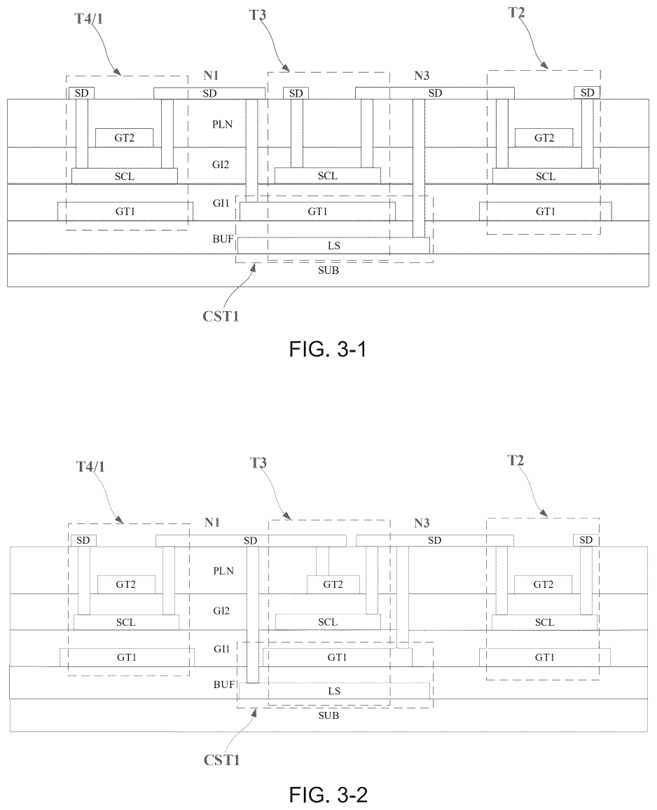

In an embodiment of the present disclosure, as shown in FIG. 3-1, the display panel has a base substrate SUB, a light-shielding metal layer LS, an inorganic buffer layer BUF, a first gate layer GT1, a first gate insulating layer GI1, a semiconductor layer SCL, a second gate insulating layer GI2, a second gate layer GT2, a planarization layer PLN and a source-drain metal layer SD that are stacked in sequence. A material of the semiconductor layer SCL is a metal oxide semiconductor material. It can be understood that at least a portion of the semiconductor layer SCL can be conductive.

In an example, a material of the first gate insulating layer GI1 is silicon oxide, e.g., a dense SiOx material.

In an example, a material of the inorganic buffer layer BUF is a silicon nitride (SiNx) material.

In an example, a material of the second gate insulating layer GI2 is silicon oxide, e.g., a dense SiOx material.

In the above examples, the first gate insulating layer GI1 and the second gate insulating layer GI2 are made of the dense SiOx material, which may reduce the diffusion of hydrogen, thereby improving the performance of the metal oxide thin film transistor.

In an example of FIG. 3-1, the driving transistor T3 is a bottom-gate transistor. The driving transistor T3 includes a bottom gate located in the first gate layer GT1 and an active layer located in the semiconductor layer SCL; the active layer of the driving transistor T3 includes a channel region, as well as a first conductive region and a second conductive region that are respectively located on both sides of the channel region. Each switching transistor includes a bottom gate located in the first gate layer GT1, an active layer located in the semiconductor layer SCL, and a top gate located in the second gate layer GT2; the active layer of the switching transistor includes a channel region, as well as a first conductive region and a second conductive region that are respectively located on both sides of the channel region.

In an example of FIG. 3-2, the driving transistor T3 is a top-gate transistor. The driving transistor T3 includes a top gate located in the second gate layer GT2 and an active layer located in the semiconductor layer SCL; the active layer of the driving transistor T3 includes a channel region, as well as a first conductive region and a second conductive region that are respectively located on both sides of the channel region.

The following takes a pixel driving circuit of 5T1C (as shown in FIG. 2) as an example to exemplarily introduce the pixel driving circuit.

In an example of FIG. 2, the pixel driving circuit includes a gate reset transistor T1, an electrode reset transistor T2, a driving transistor T3, a data writing transistor T4, a first light-emitting control transistor T5, and a storage capacitor CST1. In the pixel driving circuit, the gate reset transistor T1, the electrode reset transistor T2, the data writing transistor T4 and the first light-emitting control transistor T5 are all switching transistors. A terminal of the gate reset transistor T1 is used to load a first initialization voltage Vinit1, another terminal of the gate reset transistor T1 is electrically connected to a first node N1, and a control terminal of the gate reset transistor T1 is used to load a second scan signal Gate2. A terminal of the electrode reset transistor T2 is used to load a second initialization voltage Vinit2, another terminal of the electrode reset transistor T2 is electrically connected to a third node N3, and a control terminal of the electrode reset transistor T2 is used to load a third scan signal Gate3. A terminal of the driving transistor T3 is electrically connected to a second node N2, another terminal of the driving transistor T3 is electrically connected to the third node N3, and a control terminal of the driving transistor T3 is electrically connected to the first node N1. A terminal of the data writing transistor T4 is used to load a data voltage Vdata, another terminal of the data writing transistor T4 is electrically connected to the first node N1, and a control terminal of the data writing transistor T4 is used to load a first scan signal Gate1. A terminal of the first light-emitting control transistor T5 is used to load a first driving power supply voltage VDD, another terminal of the first light-emitting control transistor T5 is electrically connected to the second node N2, and a control terminal of the first light-emitting control transistor T5 is used to load a first light-emitting control signal EM. A terminal of the storage capacitor CST1 is electrically connected to the first node N1, and another terminal of the storage capacitor CST1 is electrically connected to the third node N3.

In an example of the pixel driving circuit, as shown in FIG. 2 and FIG. 3-1 (in which the driving transistor T3 is a bottom-gate transistor), the switching transistors include the first light-emitting control transistor T5 for transmitting the first driving power supply voltage VDD. The first light-emitting control transistor T5 includes a bottom gate located in the first gate layer GT1, an active layer located in the semiconductor layer SCL, and a top gate located in the second gate layer GT2. The top gate and bottom gate of the first light-emitting control transistor T5 are both used to load the first light-emitting control signal EM, and a first conductive region of the first light-emitting control transistor T5 is used to load the first driving power supply voltage VDD. In this embodiment, the first driving power supply voltage VDD is at a high level. A second conductive region of the first light-emitting control transistor T5 is electrically connected to a first conductive region of the driving transistor T3 through a conductive structure to form the second node N2.

In an example of the pixel driving circuit, as shown in FIG. 2 and FIG. 3-1 (in which the driving transistor T3 is a bottom-gate transistor), the switching transistors includes the gate reset transistor T1 for resetting the bottom gate of the driving transistor T3 and the data writing transistor T4 for loading the data voltage Vdata. The data writing transistor T4 includes a bottom gate located in the first gate layer GT1, an active layer located in the semiconductor layer SCL, and a top gate located in the second gate layer GT2. The top gate and bottom gate of the data writing transistor T4 are both used to load the first scan signal Gate1, and a first conductive region of the data writing transistor T4 is used to load the data voltage Vdata. The gate reset transistor T1 includes a bottom gate located in the first gate layer GT1, an active layer located in the semiconductor layer SCL, and a top gate located in the second gate layer GT2. The bottom gate and top gate of the gate reset transistor T1 are both used to load the second scan signal Gate2, and a first conductive region of the gate reset transistor T1 is used to load the first initialization voltage Vinit1. A second conductive region of the data writing transistor T4, a second conductive region of the gate reset transistor T1, and the bottom gate of the driving transistor T3 are electrically connected to each other through a conductive structure, to form the first node N1.

In an example of the pixel driving circuit, as shown in FIG. 2 and FIG. 3-1 (in which the driving transistor T3 is a bottom-gate transistor), a first electrode plate of the storage capacitor CST1 serves as the bottom gate of the driving transistor T3, a second electrode plate of the storage capacitor CST1 is located in the light-shielding metal layer LS, and the first electrode plate of the storage capacitor CST1 is electrically connected to the first node N1. In this way, the thickness of the display panel may be reduced to achieve lightness and thinness.

In an example of the pixel driving circuit, as shown in FIG. 2 and FIG. 3-1 (in which the driving transistor T3 is a bottom-gate transistor), the switching transistors further include the electrode reset transistor T2 for resetting a pixel electrode. The electrode reset transistor T2 includes a bottom gate located in the first gate layer GT1, an active layer located in the semiconductor layer SCL, and a top gate located in the second gate layer GT2. The top gate and bottom gate of the electrode reset transistor T2 are both used to load the third scan signal Gate3, and a first conductive region of the electrode reset transistor T2 is used to load the second initialization voltage Vinit2. A second conductive region of the electrode reset transistor T2, the second electrode plate of the storage capacitor CST1, a second conductive region of the driving transistor T3 and the pixel electrode are electrically connected through a conductive structure to form the third node N3, so as to reset the pixel electrode of the light-emitting element OLED and eliminate the influence of the residual voltage on the light-emitting element OLED.

An anode (i.e., the pixel electrode described above) of the light-emitting element OLED is electrically connected to the second conductive region of the driving transistor T3, and a cathode of the light-emitting element OLED is connected to a second driving power supply VSS. Specifically, a voltage of the second driving power supply VSS is at a low level.

In another example of the pixel driving circuit, as shown in FIG. 2 and FIG. 3-2 (in which the driving transistor T3 is a top-gate transistor), the switching transistors include the first light-emitting control transistor T5 for transmitting the first driving power supply voltage VDD. The first light-emitting control transistor T5 includes a bottom gate located in the first gate layer GT1, an active layer located in the semiconductor layer SCL, and a top gate located in the second gate layer GT2. The top gate and bottom gate of the first light-emitting control transistor T5 are both used to load the first light-emitting control signal EM, and a first conductive region of the first light-emitting control transistor T5 is used to load the first driving power supply voltage VDD. In this embodiment, the first driving power supply voltage VDD is at a high level. A second conductive region of the first light-emitting control transistor T5 is electrically connected to a first conductive region of the driving transistor T3 through a conductive structure to form the second node N2.

In another example of the pixel driving circuit, as shown in FIG. 2 and FIG. 3-2 (in which the driving transistor T3 is a top-gate transistor), the switching transistors includes the gate reset transistor T1 for resetting the top gate of the driving transistor T3 and the data writing transistor T4 for loading the data voltage Vdata. The data writing transistor T4 includes a bottom gate located in the first gate layer GT1, an active layer located in the semiconductor layer SCL, and a top gate located in the second gate layer GT2. The top gate and bottom gate of the data writing transistor T4 are both used to load the first scan signal Gate1, and a first conductive region of the data writing transistor T4 is used to load the data voltage Vdata. The gate reset transistor T1 includes a bottom gate located in the first gate layer GT1, an active layer located in the semiconductor layer SCL, and a top gate located in the second gate layer GT2. The bottom gate and top gate of the gate reset transistor T1 are both used to load the second scan signal Gate2, and a first conductive region of the gate reset transistor T1 is used to load the first initialization voltage Vinit1. A second conductive region of the data writing transistor T4, a second conductive region of the gate reset transistor T1, and the top gate of the driving transistor T3 are electrically connected to each other through a conductive structure, to form the first node N1.

In another example of the pixel driving circuit, as shown in FIG. 2 and FIG. 3-2 (in which the driving transistor T3 is a top-gate transistor), a second electrode plate of the storage capacitor CST1 is located in the light-shielding metal layer LS and is electrically connected to the first node N1, and a first electrode plate of the storage capacitor CST1 is located in the first gate layer GT1. In this way, the thickness of the display panel may be reduced to achieve lightness and thinness.

In another example of the pixel driving circuit, as shown in FIG. 2 and FIG. 3-2 (in which the driving transistor T3 is a top-gate transistor), the switching transistors further include the electrode reset transistor T2 for resetting a pixel electrode. The electrode reset transistor T2 includes a bottom gate located in the first gate layer GT1, an active layer located in the semiconductor layer SCL, and a top gate located in the second gate layer GT2. The top gate and bottom gate of the electrode reset transistor T2 are both used to load the third scan signal Gate3, and a first conductive region of the electrode reset transistor T2 is used to load the second initialization voltage Vinit2. A second conductive region of the electrode reset transistor T2, the first electrode plate of the storage capacitor CST1, a second conductive region of the driving transistor T3 and the pixel electrode are electrically connected through a conductive structure to form the third node N3, so as to reset the pixel electrode of the light-emitting element OLED and eliminate the influence of the residual voltage on the light-emitting element OLED.

An anode (i.e., the pixel electrode described above) of the light-emitting element OLED is electrically connected to the second conductive region of the driving transistor T3, and a cathode of the light-emitting element OLED is connected to a second driving power supply VSS. Specifically, a voltage of the second driving power supply VSS is at a low level.

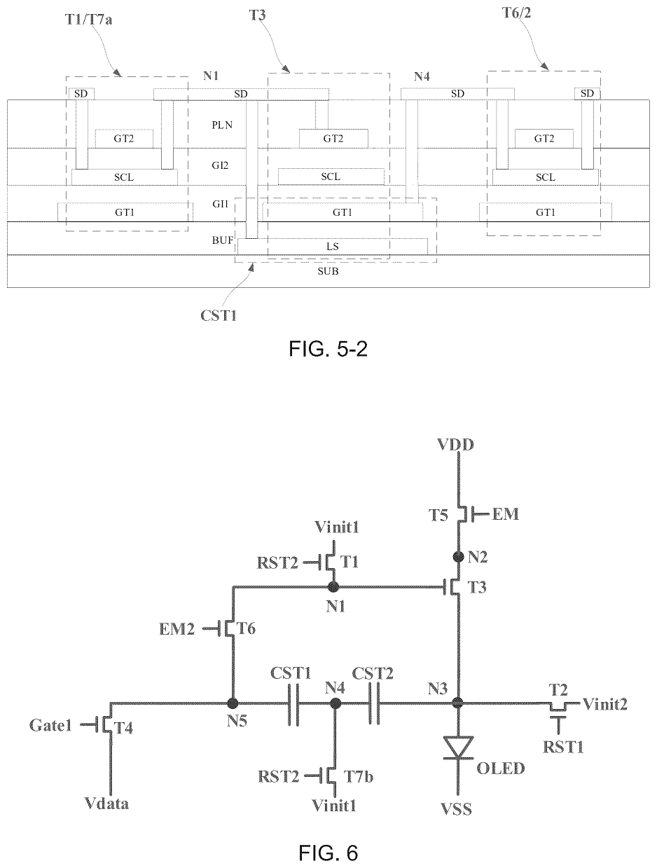

In an example of FIG. 5-1, the driving transistor T3 is a bottom-gate transistor. It can be understood that in other examples of the present disclosure, the driving transistor T3 can be a top-gate transistor. For example, in an example of FIG. 5-2, the driving transistor T3 is the top-gate transistor.

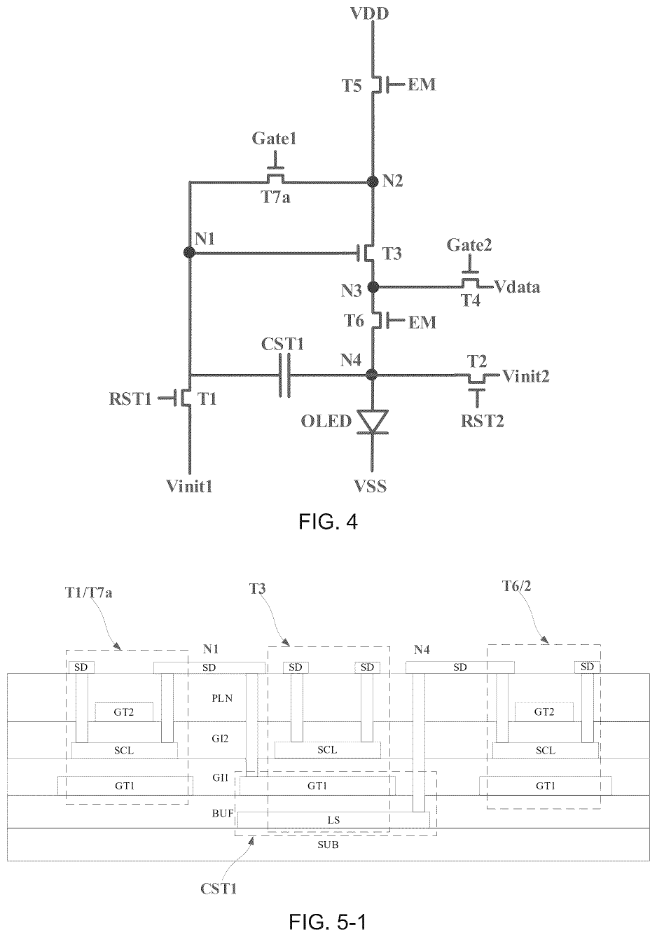

The following takes a pixel driving circuit of 7T1C (as shown in FIG. 4) as an example to exemplarily introduce the pixel driving circuit.

In an example of FIG. 4, the pixel driving circuit includes a gate reset transistor T1, an electrode reset transistor T2, a driving transistor T3, a data writing transistor T4, a first light-emitting control transistor T5, a second light-emitting control transistor T6, a threshold compensation transistor T7a, and a storage capacitor CST1. In the pixel driving circuit, the gate reset transistor T1, the electrode reset transistor T2, the data writing transistor T4, the first light-emitting control transistor T5, the second light-emitting control transistor T6 and the threshold compensation transistor T7a are all switching transistors. A terminal of the gate reset transistor T1 is used to load a first initialization voltage Vinit1, another terminal of the gate reset transistor T1 is electrically connected to a first node N1, and a control terminal of the gate reset transistor T1 is used to load a first reset control signal RST1. A terminal of the electrode reset transistor T2 is used to load a second initialization voltage Vinit2, another terminal of the electrode reset transistor T2 is electrically connected to a fourth node N4, and a control terminal of the electrode reset transistor T2 is used to load a second reset control signal RST2. A terminal of the driving transistor T3 is electrically connected to a second node N2, another terminal of the driving transistor T3 is electrically connected to a third node N3, and a control terminal of the driving transistor T3 is electrically connected to the first node N1. A terminal of the data writing transistor T4 is used to load a data voltage Vdata, another terminal of the data writing transistor T4 is electrically connected to the third node N1, and a control terminal of the data writing transistor T4 is used to load a second scan signal Gate2. A terminal of the first light-emitting control transistor T5 is used to load a first driving power supply voltage VDD, another terminal of the first light-emitting control transistor T5 is electrically connected to the second node N2, and a control terminal of the first light-emitting control transistor T5 is used to load a first light-emitting control signal EM. A terminal of the second light-emitting control transistor T6 is electrically connected to the third node N3, another terminal of the second light-emitting control transistor T6 is electrically connected to the fourth node N4, and a control terminal of the second light-emitting control transistor T6 is used to load the first light-emitting control signal EM. A terminal of the threshold compensation transistor T7a is electrically connected to the second node N2, another terminal of the threshold compensation transistor T7a is electrically connected to the first node N1, and a control terminal of the threshold compensation transistor T7a is used to load a first scan signal Gate1. A terminal of the storage capacitor CST1 is electrically connected to the first node N1, and another terminal of the storage capacitor CST1 is electrically connected to the fourth node N4.

In an example of the pixel driving circuit, as shown in FIG. 4 and FIG. 5-1 (in which the driving transistor T3 is a bottom-gate transistor), the switching transistors include the gate reset transistor T1 for resetting the bottom gate of the driving transistor T3 and the threshold compensation transistor T7a. The threshold compensation transistor T7a includes a bottom gate located in the first gate layer GT1, an active layer located in the semiconductor layer SCL, and a top gate located in the second gate layer GT2. The top gate and bottom gate of the threshold compensation transistor T7a are both used to load the first scan signal Gate1, and a second conductive region of the threshold compensation transistor T7a is electrically connected to a first conductive region of the driving transistor T3. The gate reset transistor T1 includes a bottom gate located in the first gate layer GT1, an active layer located in the semiconductor layer SCL, and a top gate located in the second gate layer GT2. The bottom gate and top gate of the gate reset transistor T1 are both used to load the first reset control signal RST1, and a first conductive region of the gate reset transistor T1 is used to load the first initialization voltage Vinit1. A first electrode plate of the storage capacitor CST1 serves as the bottom gate of the driving transistor T3, and a second electrode plate of the storage capacitor CST1 is located in the light-shielding metal layer LS. The bottom gate of the driving transistor T3, a first conductive region of the threshold compensation transistor T7a, a second conductive region of the gate reset transistor T1, and the first electrode plate of the storage capacitor CST1 are electrically connected to each other through a conductive structure, to form the first node N1. By using the threshold compensation transistor T7a, it is convenient to compensate for a threshold voltage of the driving transistor T3.

In an example of the pixel driving circuit, as shown in FIG. 4 and FIG. 5-1 (in which the driving transistor T3 is a bottom-gate transistor), the switching transistors include the threshold compensation transistor T7a and the first light-emitting control transistor T5. The threshold compensation transistor T7a includes a bottom gate located in the first gate layer GT1, an active layer located in the semiconductor layer SCL, and a top gate located in the second gate layer GT2. The top gate and bottom gate of the threshold compensation transistor T7a are both used to load the first scan signal Gate1, and a second conductive region of the threshold compensation transistor T7a is electrically connected to a first conductive region of the driving transistor T3. The first light-emitting control transistor T5 includes a bottom gate located in the first gate layer GT1, an active layer located in the semiconductor layer SCL, and a top gate located in the second gate layer GT2. The bottom gate and top gate of the first light-emitting control transistor T5 are both used to load the first light-emitting control signal EM, and a first conductive region of the first light-emitting control transistor T5 is used to load the first driving power supply voltage VDD. Here, the first driving power supply voltage VDD is at a high level. The first conductive region of the driving transistor T3, a second conductive region of the first light-emitting control transistor T5, and the second conductive region of the threshold compensation transistor T7a are electrically connected to each other through a conductive structure, to form the second node N2.

In an example of the pixel driving circuit, as shown in FIG. 4 and FIG. 5-1 (in which the driving transistor T3 is a bottom-gate transistor), the switching transistors include the data writing transistor T4 and the second light-emitting control transistor T6. The data writing transistor T4 includes a bottom gate located in the first gate layer GT1, an active layer located in the semiconductor layer SCL, and a top gate located in the second gate layer GT2. The bottom gate and top gate of the data writing transistor T4 are both used to load the second scan signal Gate2, and a first conductive region of the data writing transistor T4 is used to load the data voltage Vdata. The second light-emitting control transistor T6 includes a bottom gate located in the first gate layer GT1, an active layer located in the semiconductor layer SCL, and a top gate located in the second gate layer GT2. The bottom gate and top gate of the second light-emitting control transistor T6 are both used to load the first light-emitting control signal EM, and a second conductive region of the second light-emitting control transistor T6 is electrically connected to a pixel electrode. A second conductive region of the driving transistor T3, a second conductive region of the data writing transistor T4, and a first conductive region of the second light-emitting control transistor T6 are electrically connected through a conductive structure, to form the third node N3.

In an example of the pixel driving circuit, as shown in FIG. 4 and FIG. 5-1 (in which the driving transistor T3 is a bottom-gate transistor), the switching transistors include the second light-emitting control transistor T6 and the electrode reset transistor T2 for resetting the pixel electrode. The second light-emitting control transistor T6 includes a bottom gate located in the first gate layer GT1, an active layer located in the semiconductor layer SCL, and a top gate located in the second gate layer GT2. The bottom gate and top gate of the second light-emitting control transistor T6 are both used to load the first light-emitting control signal EM, and a second conductive region of the second light-emitting control transistor T6 is electrically connected to the pixel electrode. The electrode reset transistor T2 includes a bottom gate located in the first gate layer GT1, an active layer located in the semiconductor layer SCL, and a top gate located in the second gate layer GT2. The top gate and bottom gate of the electrode reset transistor T2 are both used to load the second reset control signal RST2, and a first conductive region of the electrode reset transistor T2 is used to load the second initialization voltage Vinit2.

A first electrode plate of the storage capacitor CST1 serves as the bottom gate of the driving transistor T3, a second electrode plate of the storage capacitor CST1 is located in the light-shielding metal layer LS. A second conductive region of the electrode reset transistor T2, the second electrode plate of the storage capacitor CST1, the second conductive region of the second light-emitting control transistor T6 and the pixel electrode are electrically connected through a conductive structure to form the fourth node N4, so as to reset the pixel electrode of the light-emitting element OLED and eliminate the influence of the residual voltage on the light-emitting element OLED.

In addition, an anode (i.e., the pixel electrode described above) of the light-emitting element OLED is electrically connected to the second conductive region of the second light-emitting control transistor T6, and a cathode of the light-emitting element OLED is connected to a second driving power supply VSS. Specifically, a voltage of the second driving power supply VSS is at a low level.

In another example of the pixel driving circuit, as shown in FIG. 4 and FIG. 5-2 (in which the driving transistor T3 is a top-gate transistor), the switching transistors include the gate reset transistor T1 for resetting the top gate of the driving transistor T3 and the threshold compensation transistor T7a. The threshold compensation transistor T7a includes a bottom gate located in the first gate layer GT1, an active layer located in the semiconductor layer SCL, and a top gate located in the second gate layer GT2. The top gate and bottom gate of the threshold compensation transistor T7a are both used to load the first scan signal Gate1, and a second conductive region of the threshold compensation transistor T7a is electrically connected to a first conductive region of the driving transistor T3. The gate reset transistor T1 includes a bottom gate located in the first gate layer GT1, an active layer located in the semiconductor layer SCL, and a top gate located in the second gate layer GT2. The bottom gate and top gate of the gate reset transistor T1 are both used to load the first reset control signal RST1, and a first conductive region of the gate reset transistor T1 is used to load the first initialization voltage Vinit1. A second electrode plate of the storage capacitor CST1 is located in the light-shielding metal layer LS. The top gate of the driving transistor T3, a first conductive region of the threshold compensation transistor T7a, a second conductive region of the gate reset transistor T1, and the second electrode plate of the storage capacitor CST1 are electrically connected to each other through a conductive structure, to form the first node N1. By using the threshold compensation transistor T7a, it is convenient to compensate for a threshold voltage of the driving transistor T3.

In another example of the pixel driving circuit, as shown in FIG. 4 and FIG. 5-2 (in which the driving transistor T3 is a top-gate transistor), the switching transistors include the threshold compensation transistor T7a and the first light-emitting control transistor T5. The threshold compensation transistor T7a includes a bottom gate located in the first gate layer GT1, an active layer located in the semiconductor layer SCL, and a top gate located in the second gate layer GT2. The top gate and bottom gate of the threshold compensation transistor T7a are both used to load the first scan signal Gate1, and a second conductive region of the threshold compensation transistor T7a is electrically connected to a first conductive region of the driving transistor T3. The first light-emitting control transistor T5 includes a bottom gate located in the first gate layer GT1, an active layer located in the semiconductor layer SCL, and a top gate located in the second gate layer GT2. The bottom gate and top gate of the first light-emitting control transistor T5 are both used to load the first light-emitting control signal EM, and a first conductive region of the first light-emitting control transistor T5 is used to load the first driving power supply voltage VDD. Here, the first driving power supply voltage VDD is at a high level. The first conductive region of the driving transistor T3, a second conductive region of the first light-emitting control transistor T5, and the second conductive region of the threshold compensation transistor T7a are electrically connected to each other through a conductive structure, to form the second node N2.

In another example of the pixel driving circuit, as shown in FIG. 4 and FIG. 5-2 (in which the driving transistor T3 is a top-gate transistor), the switching transistors include the data writing transistor T4 and the second light-emitting control transistor T6. The data writing transistor T4 includes a bottom gate located in the first gate layer GT1, an active layer located in the semiconductor layer SCL, and a top gate located in the second gate layer GT2. The bottom gate and top gate of the data writing transistor T4 are both used to load the second scan signal Gate2, and a first conductive region of the data writing transistor T4 is used to load the data voltage Vdata. The second light-emitting control transistor T6 includes a bottom gate located in the first gate layer GT1, an active layer located in the semiconductor layer SCL, and a top gate located in the second gate layer GT2. The bottom gate and top gate of the second light-emitting control transistor T6 are both used to load the first light-emitting control signal EM, and a second conductive region of the second light-emitting control transistor T6 is electrically connected to a pixel electrode. A second conductive region of the driving transistor T3, a second conductive region of the data writing transistor T4, and a first conductive region of the second light-emitting control transistor T6 are electrically connected through a conductive structure, to form the third node N3.

In another example of the pixel driving circuit, as shown in FIG. 4 and FIG. 5-2 (in which the driving transistor T3 is a top-gate transistor), the switching transistors include the second light-emitting control transistor T6 and the electrode reset transistor T2 for resetting the pixel electrode. The second light-emitting control transistor T6 includes a bottom gate located in the first gate layer GT1, an active layer located in the semiconductor layer SCL, and a top gate located in the second gate layer GT2. The bottom gate and top gate of the second light-emitting control transistor T6 are both used to load the first light-emitting control signal EM, and a second conductive region of the second light-emitting control transistor T6 is electrically connected to the pixel electrode. The electrode reset transistor T2 includes a bottom gate located in the first gate layer GT1, an active layer located in the semiconductor layer SCL, and a top gate located in the second gate layer GT2. The top gate and bottom gate of the electrode reset transistor T2 are both used to load the second reset control signal RST2, and a first conductive region of the electrode reset transistor T2 is used to load the second initialization voltage Vinit2.

A second electrode plate of the storage capacitor CST1 is located in the light-shielding metal layer LS. A second conductive region of the electrode reset transistor T2, a first electrode plate of the storage capacitor CST1, the second conductive region of the second light-emitting control transistor T6 and the pixel electrode are electrically connected through a conductive structure to form the fourth node N4, so as to reset the pixel electrode of the light-emitting element OLED and eliminate the influence of the residual voltage on the light-emitting element OLED.

In addition, an anode (i.e., the pixel electrode described above) of the light-emitting element OLED is electrically connected to the second conductive region of the second light-emitting control transistor T6, and a cathode of the light-emitting element OLED is connected to a second driving power supply VSS. Specifically, a voltage of the second driving power supply VSS is at a low level.

In examples of FIGS. 7-1 and 8-1, the driving transistor T3 is a bottom-gate transistor. It can be understood that in other examples of the present disclosure, the driving transistor T3 can be a top-gate transistor. For example, in examples of FIGS. 7-2 and 8-2, the driving transistor T3 is the top-gate transistor.

The following takes a pixel driving circuit of 7T2C (as shown in FIG. 6) as an example to exemplarily introduce the pixel driving circuit.

In an example of FIG. 6, the pixel driving circuit includes a gate reset transistor T1, an electrode reset transistor T2, a driving transistor T3, a data writing transistor T4, a first light-emitting control transistor T5, a second light-emitting control transistor T6, a voltage-stabilizing transistor T7b, a storage capacitor CST1, and an auxiliary capacitor CST2. In the pixel driving circuit, the gate reset transistor T1, the electrode reset transistor T2, the data writing transistor T4, the first light-emitting control transistor T5, the second light-emitting control transistor T6 and the voltage-stabilizing transistor T7b are all switching transistors. A terminal of the gate reset transistor T1 is used to load a first initialization voltage Vinit1, another terminal of the gate reset transistor T1 is electrically connected to a first node N1, and a control terminal of the gate reset transistor T1 is used to load a second reset control signal RST2. A terminal of the electrode reset transistor T2 is used to load a second initialization voltage Vinit2, another terminal of the electrode reset transistor T2 is electrically connected to a third node N3, and a control terminal of the electrode reset transistor T2 is used to load a first reset control signal RST1. A terminal of the driving transistor T3 is electrically connected to a second node N2, another terminal of the driving transistor T3 is electrically connected to the third node N3, and a control terminal of the driving transistor T3 is electrically connected to the first node N1. A terminal of the data writing transistor T4 is used to load a data voltage Vdata, another terminal of the data writing transistor T4 is electrically connected to a fifth node N5, and a control terminal of the data writing transistor T4 is used to load a first scan signal Gate1. A terminal of the first light-emitting control transistor T5 is used to load a first driving power supply voltage VDD, another terminal of the first light-emitting control transistor T5 is electrically connected to the second node N2, and a control terminal of the first light-emitting control transistor T5 is used to load a first light-emitting control signal EM. A terminal of the second light-emitting control transistor T6 is electrically connected to the first node N1, another terminal of the second light-emitting control transistor T6 is electrically connected to the fifth node N5, and a control terminal of the second light-emitting control transistor T6 is used to load a second light-emitting control signal EM2. A terminal of the voltage-stabilizing transistor T7b is used to load the first initialization voltage Vinit1, another terminal of the voltage-stabilizing transistor T7b is electrically connected to a fourth node N4, and a control terminal of the voltage-stabilizing transistor T7b is used to load the second reset control signal RST2. A terminal of the storage capacitor CST1 is electrically connected to the fifth node N5, and another terminal of the storage capacitor CST1 is electrically connected to the fourth node N4. A terminal of the auxiliary capacitor CST2 is electrically connected to the third node N3, and another terminal of the auxiliary capacitor CST2 is electrically connected to the fourth node N4.

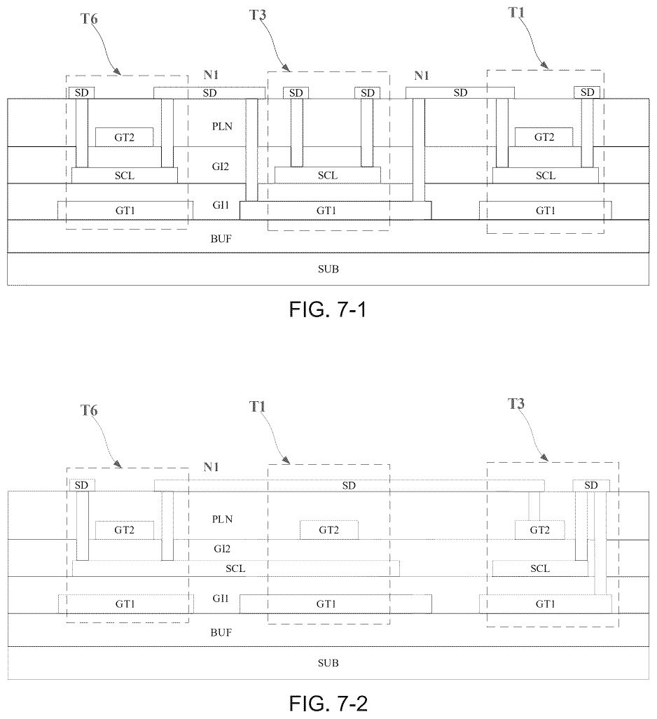

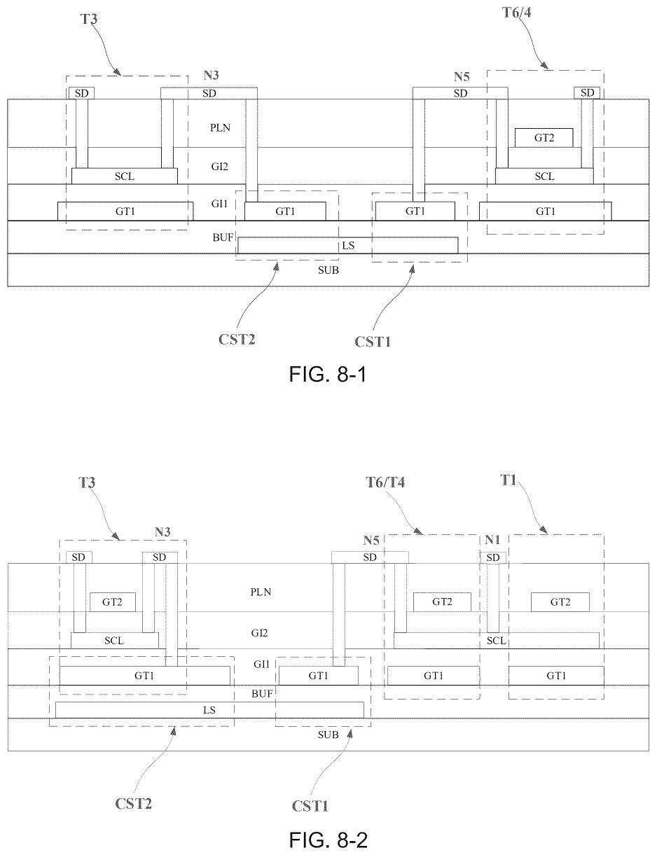

In an example of the pixel driving circuit, as shown in FIG. 6, FIG. 7-1 (in which the driving transistor T3 is a bottom-gate transistor), and FIG. 8-1 (in which the driving transistor T3 is a bottom-gate transistor), the switching transistors include the second light-emitting control transistor T6, the gate reset transistor T1 and the data writing transistor T4. The second light-emitting control transistor T6 includes a bottom gate located in the first gate layer GT1, an active layer located in the semiconductor layer SCL, and a top gate located in the second gate layer GT2. The bottom gate and top gate of the second light-emitting control transistor T6 are both used to load the second light-emitting control signal EM2. The gate reset transistor T1 includes a bottom gate located in the first gate layer GT1, an active layer located in the semiconductor layer SCL, and a top gate located in the second gate layer GT2. The bottom gate and top gate of the gate reset transistor T1 are both used to load the second reset control signal RST2, and a first conductive region of the gate reset transistor T1 is used to load the first initialization voltage Vinit1. A second conductive region of the second light-emitting control transistor T6, a second conductive region of the gate reset transistor T1, and the bottom gate of the driving transistor T3 are all electrically connected through a conductive structure, to form the first node N1.

In an example of the pixel driving circuit, as shown in FIG. 6 and FIG. 8-1 (in which the driving transistor T3 is a bottom-gate transistor), the data writing transistor T4 includes a bottom gate located in the first gate layer GT1, an active layer located in the semiconductor layer SCL, and a top gate located in the second gate layer GT2. The bottom gate and top gate of the data writing transistor T4 are both used to load the first scan signal Gate1, and a first conductive region of the data writing transistor T4 is used to load the data voltage Vdata. The storage capacitor CST1 includes a first electrode plate located in the first gate layer GT1 and a second electrode plate located in the light-shielding metal layer LS. A second conductive region of the data writing transistor T4, a first conductive region of the second light-emitting control transistor T6, and the first electrode plate of the storage capacitor CST1 are electrically connected to each other through a conductive structure, to form the fifth node N5.

In an example of the pixel driving circuit, as shown in FIG. 6 (in which the driving transistor T3 is a bottom-gate transistor), the switching transistors include the first light-emitting control transistor T5. The first light-emitting control transistor T5 includes a bottom gate located in the first gate layer GT1, an active layer located in the semiconductor layer SCL, and a top gate located in the second gate layer GT2. The top gate and bottom gate of the first light-emitting control transistor T5 are both used to load the first light-emitting control signal EM, and a first conductive region of the first light-emitting control transistor T5 is used to load the first driving power supply voltage VDD. In this embodiment, the first driving power supply voltage VDD is at a high level. A second conductive region of the first light-emitting control transistor T5 is electrically connected to a first conductive region of the driving transistor T3 through a conductive structure, to form the second node N2.

In an example of the pixel driving circuit, as shown in FIGS. 6, 7-1 and 8-1 (in which the driving transistor T3 is a bottom-gate transistor), the pixel driving circuit further includes the auxiliary capacitor CST2. The auxiliary capacitor CST2 includes a first electrode plate located in the first gate layer GT1 and a second electrode plate located in the light-shielding metal layer LS. The switching transistors include the voltage-stabilizing transistor T7b, the data writing transistor T4 and the electrode reset transistor T2. The voltage-stabilizing transistor T7b includes a bottom gate located in the first gate layer GT1, an active layer located in the semiconductor layer SCL, and a top gate located in the second gate layer GT2. The bottom gate and top gate of the voltage-stabilizing transistor T7b are both used to load the second reset control signal RST2, and a first conductive region of the voltage-stabilizing transistor T7b is used to load the first initialization voltage Vinit1.

The data writing transistor T4 includes a bottom gate located in the first gate layer GT1, an active layer located in the semiconductor layer SCL, and a top gate located in the second gate layer GT2. The bottom gate and top gate of the data writing transistor T4 are both used to load the first scan signal Gate1, and a first conductive region of the data writing transistor T4 is used to load the data voltage Vdata.

The second electrode plate of the auxiliary capacitor CST2, the second electrode plate of the storage capacitor CST1, and a second conductive region of the voltage-stabilizing transistor T7b are electrically connected to each other through a conductive structure, to form the fourth node N4.

In an example of the pixel driving circuit, the electrode reset transistor T2 includes a bottom gate located in the first gate layer GT1, an active layer located in the semiconductor layer SCL, and a top gate located in the second gate layer GT2. The top gate and bottom gate of the electrode reset transistor T2 are both used to load the first reset control signal RST1, and a first conductive region of the electrode reset transistor T2 is used to load the second initialization voltage Vinit2.

In an example of the pixel driving circuit, as shown in FIG. 6 and FIG. 8-1 (in which the driving transistor T3 is a bottom-gate transistor), a second conductive region of the electrode reset transistor T2, a second conductive region of the driving transistor T3, the first electrode plate of the auxiliary capacitor CST2, and a pixel electrode of the light-emitting element OLED are electrically connected through a conductive structure to form the third node N3, so as to reset the pixel electrode of the light-emitting element OLED and eliminate the influence of the residual voltage on the light-emitting element OLED.

In addition, an anode (i.e., the pixel electrode described above) of the light-emitting element OLED is electrically connected to the second conductive region of the driving transistor T3, and a cathode of the light-emitting element OLED is connected to a second driving power supply VSS. Specifically, a voltage of the second driving power supply VSS is at a low level.

It should be noted that, since the driving transistor T3 and the switching transistors are described by taking N-type transistors as an example, the first conductive regions of the driving transistor T3 and the switching transistors are all sources, and the second conductive regions of the driving transistor T3 and the switching transistors are all drains.

In another example of the pixel driving circuit, as shown in FIG. 6, FIG. 7-2 (in which the driving transistor T3 is a top-gate transistor), and FIG. 8-2 (in which the driving transistor T3 is a top-gate transistor), the switching transistors include the second light-emitting control transistor T6, the gate reset transistor T1 and the data writing transistor T4. The second light-emitting control transistor T6 includes a bottom gate located in the first gate layer GT1, an active layer located in the semiconductor layer SCL, and a top gate located in the second gate layer GT2. The bottom gate and top gate of the second light-emitting control transistor T6 are both used to load the second light-emitting control signal EM2. The gate reset transistor T1 includes a bottom gate located in the first gate layer GT1, an active layer located in the semiconductor layer SCL, and a top gate located in the second gate layer GT2. The bottom gate and top gate of the gate reset transistor T1 are both used to load the second reset control signal RST2, and a first conductive region of the gate reset transistor T1 is used to load the first initialization voltage Vinit1. A second conductive region of the second light-emitting control transistor T6, a second conductive region of the gate reset transistor T1, and the top gate of the driving transistor T3 are all electrically connected through a conductive structure, to form the first node N1.

In another example of the pixel driving circuit, as shown in FIG. 6 and FIG. 8-2 (in which the driving transistor T3 is a top-gate transistor), the data writing transistor T4 includes a bottom gate located in the first gate layer GT1, an active layer located in the semiconductor layer SCL, and a top gate located in the second gate layer GT2. The bottom gate and top gate of the data writing transistor T4 are both used to load the first scan signal Gate1, and a first conductive region of the data writing transistor T4 is used to load the data voltage Vdata. The storage capacitor CST1 includes a first electrode plate located in the first gate layer GT1 and a second electrode plate located in the light-shielding metal layer LS. A second conductive region of the data writing transistor T4, a first conductive region of the second light-emitting control transistor T6, and the first electrode plate of the storage capacitor CST1 are electrically connected to each other through a conductive structure, to form the fifth node N5.

In another example of the pixel driving circuit, as shown in FIG. 6 (in which the driving transistor T3 is a top-gate transistor), the switching transistors include the first light-emitting control transistor T5. The first light-emitting control transistor T5 includes a bottom gate located in the first gate layer GT1, an active layer located in the semiconductor layer SCL, and a top gate located in the second gate layer GT2. The top gate and bottom gate of the first light-emitting control transistor T5 are both used to load the first light-emitting control signal EM, and a first conductive region of the first light-emitting control transistor T5 is used to load the first driving power supply voltage VDD. In this embodiment, the first driving power supply voltage VDD is at a high level. A second conductive region of the first light-emitting control transistor T5 is electrically connected to a first conductive region of the driving transistor T3 through a conductive structure, to form the second node N2.

In another example of the pixel driving circuit, as shown in FIGS. 6, 7-2 and 8-2 (in which the driving transistor T3 is a top-gate transistor), the pixel driving circuit further includes the auxiliary capacitor CST2. The auxiliary capacitor CST2 includes a first electrode plate located in the first gate layer GT1 and a second electrode plate located in the light-shielding metal layer LS. The switching transistors include the voltage-stabilizing transistor T7b, the data writing transistor T4 and the electrode reset transistor T2. The voltage-stabilizing transistor T7b includes a bottom gate located in the first gate layer GT1, an active layer located in the semiconductor layer SCL, and a top gate located in the second gate layer GT2. The bottom gate and top gate of the voltage-stabilizing transistor T7b are both used to load the second reset control signal RST2, and a first conductive region of the voltage-stabilizing transistor T7b is used to load the first initialization voltage Vinit1.

The data writing transistor T4 includes a bottom gate located in the first gate layer GT1, an active layer located in the semiconductor layer SCL, and a top gate located in the second gate layer GT2. The bottom gate and top gate of the data writing transistor T4 are both used to load the first scan signal Gate1, and a first conductive region of the data writing transistor T4 is used to load the data voltage Vdata.

The second electrode plate of the auxiliary capacitor CST2, the second electrode plate of the storage capacitor CST1, and a second conductive region of the voltage-stabilizing transistor T7b are electrically connected to each other through a conductive structure, to form the fourth node N4.

In another example of the pixel driving circuit (in which the driving transistor T3 is a top-gate transistor), the electrode reset transistor T2 includes a bottom gate located in the first gate layer GT1, an active layer located in the semiconductor layer SCL, and a top gate located in the second gate layer GT2. The top gate and bottom gate of the electrode reset transistor T2 are both used to load the first reset control signal RST1, and a first conductive region of the electrode reset transistor T2 is used to load the second initialization voltage Vinit2.

In another example of the pixel driving circuit, as shown in FIG. 6 and FIG. 8-2 (in which the driving transistor T3 is a top-gate transistor), a second conductive region of the electrode reset transistor T2, a second conductive region of the driving transistor T3, the first electrode plate of the auxiliary capacitor CST2, and a pixel electrode of the light-emitting element OLED are electrically connected through a conductive structure to form the third node N3, so as to reset the pixel electrode of the light-emitting element OLED and eliminate the influence of the residual voltage on the light-emitting element OLED.

In addition, an anode (i.e., the pixel electrode described above) of the light-emitting element OLED is electrically connected to the second conductive region of the driving transistor T3, and a cathode of the light-emitting element OLED is connected to a second driving power supply VSS. Specifically, a voltage of the second driving power supply VSS is at a low level.

It should be noted that, since the driving transistor T3 and the switching transistors are described by taking N-type transistors as an example, the first conductive regions of the driving transistor T3 and the switching transistors are all sources, and the second conductive regions of the driving transistor T3 and the switching transistors are all drains.

In an embodiment of the present disclosure, the conductive structure is located in one or more of the light-shielding metal layer LS, the first gate layer GT1, the second gate layer GT2, the semiconductor layer SCL and the source-drain metal layer SD, as long as the various transistors are electrically connected.

In an embodiment of the present disclosure, the driving transistor T3 and the switching transistors may be fabricated using a back channel etching (BCE) process. Preferably, the driving transistor T3 and the switching transistors may be fabricated using an etch stop layer (ESL) process to reduce the influence on the semiconductor layer SCL during the etching process.

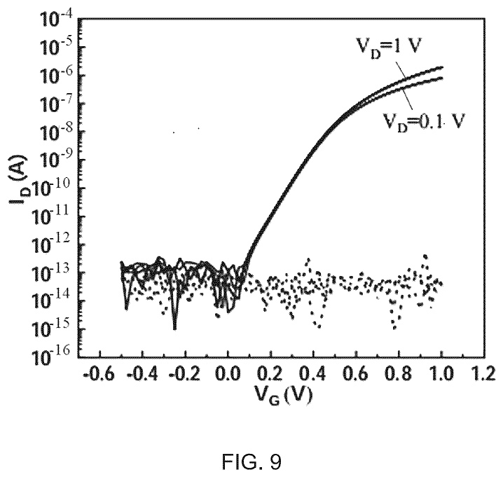

In the embodiments of the present disclosure, the SS of the dual-gate metal oxide transistor is relatively small. As shown in FIG. 9, the SS of the single-gate metal oxide transistor is greater than the SS of the dual-gate metal oxide transistor, which indicates that the switching characteristic of the single-gate metal oxide transistor is lower than that of the dual-gate metal oxide transistor. Thus, it is convenient for the low grayscale. For example, when the drain current of the thin film transistor changes by an order of magnitude (10 times), the gate voltage change corresponding to the single-gate metal oxide transistor is smaller than the gate voltage change corresponding to the dual-gate metal oxide transistor.

As shown in FIG. 9, the drain voltage of the single-gate metal oxide transistor has two states, which means that the drain voltages are 0.1 V and 1 V. It can be seen that under the same gate voltage, the drain current when the drain voltage is 1 V is greater than the drain current when the drain voltage is 0.1 V, but the change in the drain current is small. For example, when the gate voltage is 0.4 V, the drain currents in the two states are both close to 10⁻⁹ A. Although the drain voltage spans an order of magnitude, the drain current of the driving transistor T3 changes very little.

The present disclosure further provides a display panel including the pixel driving circuit described above. The display panel includes: a plurality of scan lines for providing scan signals, a plurality of data lines for providing data signals, and a plurality of pixel driving circuits electrically connected to the scan lines and data lines. At least one of the plurality of pixel driving circuits is any of the above-mentioned pixel driving circuits in the example embodiments. Since the pixel driving circuit reduces the electron mobility of the driving transistor T3, the SS of the driving transistor T3 is increased, which may better match the capabilities of the driving IC and ameliorate the low grayscale image quality of the OLED display panel.

The display apparatus using the display panel may be, for example, any product or component having a display function, such as a mobile phone, a tablet computer, a television, a notebook computer, a digital photo frame, or a navigator.

It should be noted that various steps of the method in the present disclosure are described in a specific order in the drawings. However, this does not require or imply that these steps must be performed in this specific order, or that all the steps shown must be performed to achieve the desired results. Additionally or alternatively, some steps may be omitted, multiple steps may be combined into one step, and/or one step may be decomposed into multiple steps, etc., which should all be considered part of present disclosure.

It should be understood that the present disclosure is not limited in its application to the specific construction and arrangement of components set forth in this specification. The present disclosure can have other embodiments and can be practiced and carried out in various ways. The foregoing variations and modifications fall within the scope of the present disclosure. It should be understood that the disclosure disclosed and defined in this specification extends to all alternative combinations of two or more of the separate features mentioned or evident from the text and/or drawings. All of these different combinations constitute various alternative aspects of the present disclosure. The embodiments in this specification illustrate the best mode known for carrying out the present disclosure and will enable those skilled in the art to utilize the present disclosure.

What is claimed is:

1. A pixel driving circuit, provided in a display panel to drive a light-emitting element, the pixel driving circuit comprising a driving transistor for generating a driving current, wherein a channel region of the driving transistor is made of a metal oxide semiconductor material, and the driving transistor has only one of a top gate and a bottom gate.

2. The pixel driving circuit according to claim 1, wherein the display panel has a base substrate, a light-shielding metal layer, an inorganic buffer layer, a first gate layer, a first gate insulating layer and a semiconductor layer that are stacked in sequence; and
an active layer of the driving transistor is located in the semiconductor layer, and the driving transistor has the bottom gate located in the first gate layer, wherein
the pixel driving circuit further comprises a storage capacitor, wherein a first electrode plate of the storage capacitor is located in the light-shielding metal layer of the display panel, and a second electrode plate of the storage capacitor serves as the bottom gate of the driving transistor.

3. The pixel driving circuit according to claim 1, further comprising at least one switching transistor, wherein a channel region of a switching transistor is made of a metal oxide semiconductor material.

4. The pixel driving circuit according to claim 3, wherein the switching transistor has a top gate and a bottom gate.

5. The pixel driving circuit according to claim 4, wherein the display panel has a base substrate, a light-shielding metal layer, an inorganic buffer layer, a first gate layer, a first gate insulating layer, a semiconductor layer, a second gate insulating layer, a second gate layer, a planarization layer and a source-drain metal layer that are stacked in sequence;
the driving transistor includes the bottom gate located in the first gate layer and an active layer located in the semiconductor layer, and the active layer of the driving transistor includes a channel region, and a first conductive region and a second conductive region located on both sides of the channel region; each switching transistor includes a bottom gate located in the first gate layer, an active layer located in the semiconductor layer and a top gate located in the second gate layer; and the active layer of the switching transistor includes a channel region, and a first conductive region and a second conductive region located on both sides of the channel region.

6. The pixel driving circuit according to claim 5, wherein the at least one switching transistor includes a first light-emitting control transistor;
the first light-emitting control transistor includes a bottom gate located in the first gate layer, an active layer located in the semiconductor layer, and a top gate located in the second gate layer;
the top gate and bottom gate of the first light-emitting control transistor are both used to load a first light-emitting control signal;
a first conductive region of the first light-emitting control transistor is used to load a first driving power supply voltage; and
a second conductive region of the first light-emitting control transistor is electrically connected to the first conductive region of the driving transistor through a conductive structure.

7. The pixel driving circuit according to claim 5, wherein the at least one switching transistor includes a data writing transistor for loading a data voltage and a gate reset transistor for resetting the bottom gate of the driving transistor;
the data writing transistor includes a bottom gate located in the first gate layer, an active layer located in the semiconductor layer, and a top gate located in the second gate layer; the top gate and bottom gate of the data writing transistor are both used to load a first scan signal, and a first conductive region of the data writing transistor is used to load the data voltage;
the gate reset transistor includes a bottom gate located in the first gate layer, an active layer located in the semiconductor layer, and a top gate located in the second gate layer; the bottom gate and top gate of the gate reset transistor are both used to load a second scan signal, and a first conductive region of the gate reset transistor is used to load a first initialization voltage; and
a second conductive region of the data writing transistor, a second conductive region of the gate reset transistor, and the bottom gate of the driving transistor are electrically connected to each other through a conductive structure, wherein
the pixel driving circuit further comprises a storage capacitor, wherein a first electrode plate of the storage capacitor serves as the bottom gate of the driving transistor, and a second electrode plate of the storage capacitor is located in the light-shielding metal layer.

8. The pixel driving circuit according to claim 5, further comprising a storage capacitor, wherein a first electrode plate of the storage capacitor serves as the bottom gate of the driving transistor, and a second electrode plate of the storage capacitor is located in the light-shielding metal layer;
the at least one switching transistor includes an electrode reset transistor for resetting a pixel electrode of the light-emitting element; the electrode reset transistor includes a bottom gate located in the first gate layer, an active layer located in the semiconductor layer, and a top gate located in the second gate layer; the top gate and bottom gate of the electrode reset transistor are both used to load a third scan signal, and a first conductive region of the electrode reset transistor is used to load a second initialization voltage; and
a second conductive region of the electrode reset transistor, the second electrode plate of the storage capacitor, the second conductive region of the driving transistor and the pixel electrode are electrically connected through a conductive structure.

9. The pixel driving circuit according to claim 5, further comprising a storage capacitor, wherein a first electrode plate of the storage capacitor serves as the bottom gate of the driving transistor, and a second electrode plate of the storage capacitor is located in the light-shielding metal layer;
the at least one switching transistor includes a threshold compensation transistor and a gate reset transistor for resetting the bottom gate of the driving transistor;
the threshold compensation transistor includes a bottom gate located in the first gate layer, an active layer located in the semiconductor layer, and a top gate located in the second gate layer; the top gate and bottom gate of the threshold compensation transistor are both used to load a first scan signal, and a second conductive region of the threshold compensation transistor is electrically connected to the first conductive region of the driving transistor;
the gate reset transistor includes a bottom gate located in the first gate layer, an active layer located in the semiconductor layer, and a top gate located in the second gate layer; the bottom gate and top gate of the gate reset transistor are both used to load a first reset control signal, and a first conductive region of the gate reset transistor is used to load a first initialization voltage; and
the bottom gate of the driving transistor, a first conductive region of the threshold compensation transistor, and a second conductive region of the gate reset transistor are electrically connected to each other through a conductive structure.

10. The pixel driving circuit according to claim 5, wherein the at least one switching transistor includes a threshold compensation transistor and a first light-emitting control transistor;
the threshold compensation transistor includes a bottom gate located in the first gate layer, an active layer located in the semiconductor layer, and a top gate located in the second gate layer; the top gate and bottom gate of the threshold compensation transistor are both used to load a first scan signal, and a first conductive region of the threshold compensation transistor is electrically connected to the bottom gate of the driving transistor;
the first light-emitting control transistor includes a bottom gate located in the first gate layer, an active layer located in the semiconductor layer, and a top gate located in the second gate layer; the bottom gate and top gate of the first light-emitting control transistor are both used to load a first light-emitting control signal, and a first conductive region of the first light-emitting control transistor is used to load a first driving power supply voltage; and
the first conductive region of the driving transistor, a second conductive region of the first light-emitting control transistor, and a second conductive region of the threshold compensation transistor are electrically connected to each other through a conductive structure.

11. The pixel driving circuit according to claim 5, wherein the at least one switching transistor includes a data writing transistor and a second light-emitting control transistor;
the data writing transistor includes a bottom gate located in the first gate layer, an active layer located in the semiconductor layer, and a top gate located in the second gate layer; the bottom gate and top gate of the data writing transistor are both used to load a second scan signal, and a first conductive region of the data writing transistor is used to load a data voltage;
the second light-emitting control transistor includes a bottom gate located in the first gate layer, an active layer located in the semiconductor layer, and a top gate located in the second gate layer; the bottom gate and top gate of the second light-emitting control transistor are both used to load a first light-emitting control signal, and a second conductive region of the second light-emitting control transistor is electrically connected to a pixel electrode of the light-emitting element; and
the second conductive region of the driving transistor, a second conductive region of the data writing transistor, and a first conductive region of the second light-emitting control transistor are electrically connected through a conductive structure.

12. The pixel driving circuit according to claim 5, further comprising a storage capacitor, wherein a first electrode plate of the storage capacitor serves as the bottom gate of the driving transistor, and a second electrode plate of the storage capacitor is located in the light-shielding metal layer;
the at least one switching transistor includes a second light-emitting control transistor and an electrode reset transistor for resetting a pixel electrode of the light-emitting element;
the second light-emitting control transistor includes a bottom gate located in the first gate layer, an active layer located in the semiconductor layer, and a top gate located in the second gate layer; the bottom gate and top gate of the second light-emitting control transistor are both used to load a first light-emitting control signal, and a first conductive region of the second light-emitting control transistor is electrically connected to the second conductive region of the driving transistor;
the electrode reset transistor includes a bottom gate located in the first gate layer, an active layer located in the semiconductor layer, and a top gate located in the second gate layer; the top gate and bottom gate of the electrode reset transistor are both used to load a second reset control signal, and a first conductive region of the electrode reset transistor is used to load a second initialization voltage; and
a second conductive region of the electrode reset transistor, the second electrode plate of the storage capacitor, a second conductive region of the second light-emitting control transistor and the pixel electrode are electrically connected through a conductive structure.

13. The pixel driving circuit according to claim 5, further comprising a storage capacitor, wherein the storage capacitor includes a first electrode plate located in the first gate layer and a second electrode plate located in the light-shielding metal layer;
the at least one switching transistor includes a second light-emitting control transistor, a gate reset transistor and a data writing transistor;
the second light-emitting control transistor includes a bottom gate located in the first gate layer, an active layer located in the semiconductor layer, and a top gate located in the second gate layer; the bottom gate and top gate of the second light-emitting control transistor are both used to load a second light-emitting control signal;
the gate reset transistor includes a bottom gate located in the first gate layer, an active layer located in the semiconductor layer, and a top gate located in the second gate layer; the bottom gate and top gate of the gate reset transistor are both used to load a second reset control signal, and a first conductive region of the gate reset transistor is used to load a first initialization voltage;
a second conductive region of the second light-emitting control transistor, a second conductive region of the gate reset transistor, and the bottom gate of the driving transistor are electrically connected through a conductive structure;
the data writing transistor includes a bottom gate located in the first gate layer, an active layer located in the semiconductor layer, and a top gate located in the second gate layer; the bottom gate and top gate of the data writing transistor are both used to load a first scan signal, and a first conductive region of the data writing transistor is used to load a data voltage; and
a second conductive region of the data writing transistor, a first conductive region of the second light-emitting control transistor, and the first electrode plate of the storage capacitor are electrically connected to each other through a conductive structure.

14. The pixel driving circuit according to claim 5, further comprising an auxiliary capacitor and a storage capacitor; the auxiliary capacitor includes a first electrode plate located in the first gate layer and a second electrode plate located in the light-shielding metal layer, and the storage capacitor includes a first electrode plate located in the first gate layer and a second electrode plate located in the light-shielding metal layer;
the at least one switching transistor includes a voltage-stabilizing transistor, a data writing transistor, and an electrode reset transistor;
the voltage-stabilizing transistor includes a bottom gate located in the first gate layer, an active layer located in the semiconductor layer, and a top gate located in the second gate layer; the bottom gate and top gate of the voltage-stabilizing transistor are both used to load a second reset control signal, and a first conductive region of the voltage-stabilizing transistor is used to load a first initialization voltage;
the data writing transistor is used for loading a data voltage onto the first electrode plate of the storage capacitor in response to a first scan signal;
the electrode reset transistor includes a bottom gate located in the first gate layer, an active layer located in the semiconductor layer, and a top gate located in the second gate layer; the bottom gate and top gate of the electrode reset transistor are both used to load a first reset control signal, and a first conductive region of the electrode reset transistor is used to load a second initialization voltage; and
the second electrode plate of the auxiliary capacitor, the second electrode plate of the storage capacitor, and a second conductive region of the voltage-stabilizing transistor are electrically connected to each other through a conductive structure.

15. The pixel driving circuit according to claim 6, wherein the conductive structure is located in one or more of the light-shielding metal layer, the first gate layer, the second gate layer, the semiconductor layer, and the source-drain metal layer.

16. A display panel, comprising the pixel driving circuit according to claim 1.

17. The pixel driving circuit according to claim 1, wherein the display panel has a base substrate, a light-shielding metal layer, an inorganic buffer layer, a first gate layer, a first gate insulating layer, a semiconductor layer, a second gate insulating layer, a second gate layer, a planarization layer and a source-drain metal layer that are stacked in sequence; and
an active layer of the driving transistor is located in the semiconductor layer, and the driving transistor has the top gate located in the second gate layer, wherein
the pixel driving circuit further comprises a storage capacitor, wherein a first electrode plate of the storage capacitor is located in the first gate layer, and a second electrode plate of the storage capacitor is located in the light-shielding metal layer and is electrically connected to the top gate of the driving transistor.

18. The pixel driving circuit according to claim 17, further comprising at least one switching transistor, wherein a channel region of a switching transistor is made of a metal oxide semiconductor material.

19. The pixel driving circuit according to claim 3, wherein the driving transistor and the at least one switching transistor are all etch stop layer (ESL) transistors.

20. The display panel according to claim 16, further comprising a light-emitting element electrically connected to the pixel driving circuit.
